(19) United States
(12) Patent Application Publication
(10) Pub. No.: US 2013/0070437 A1
(43) Pub. Date: Mar. 21, 2013

(54) HYBRID INTERPOSER

(71) Applicants: Ilyas Mohammed, San Jose, CA (US); Terrence Caskey, San Jose, CA (US)

(72) Inventors: Ilyas Mohammed, San Jose, CA (US); Terrence Caskey, San Jose, CA (US)

(73) Assignee: INVENSAS CORP., San Jose, CA (US)

(21) Appl. No.: 13/236,830

(22) Filed: Sep. 20, 2011

(51) Int. Cl. H05K 7/06; H05K 1/11; H05K 1/00; H01R 43/00

(52) U.S. Cl. 361/767; 29/825; 174/262; 174/258

(57) ABSTRACT

An interconnection component includes a low coefficient of thermal expansion (“CTE”) element having first and second surfaces defining a thickness, the element consisting essentially of a material having a first CTE of less than 10 parts per million per degree Celsius, the element having a plurality of contacts exposed at a first surface thereof. The component further includes a circuit panel having a dielectric element with first and second surfaces defining a thickness and a plurality of terminals exposed at the first surface, the circuit panel having a thickness greater than 50% of the thickness of the low-CTE element. A bonding layer including a dielectric material bonds the second surfaces of the circuit panel and the low CTE element to one another. Metalized vias are electrically connected with the terminals and the contacts, at least some vias extending through the bonding layer and through the thickness of the low-CTE element.

### BACKGROUND OF THE INVENTION

Interconnection components, such as interposers are used in electronic assemblies to facilitate connection between components with different connection configurations or to provide needed spacing between components in a microelectronic assembly. Interposers can include a dielectric element in the form of a sheet or layer of dielectric material having numerous conductive traces extending on or within the sheet or layer. The traces can be provided in one level or in multiple levels throughout a single dielectric layer, separated by portions of dielectric material within the layer. The interposer can also include conductive elements such as conductive vias extending through the layer of dielectric material to interconnect traces in different levels. Some interposers are used as components of microelectronic assemblies. Microelectronic assemblies generally include one or more packaged microelectronic elements such as one or more semiconductor chips mounted on a substrate. The conductive elements of the interposer can include the conductive traces and terminals that can be used for making electrical connection with a larger substrate or circuit panel in the form of a printed circuit board (“PCB”) or the like. This arrangement facilitates electrical connections needed to achieve desired functionality of the devices. The chip can be electrically connected to the traces and hence to the terminals, so that the package can be mounted to a larger circuit panel by bonding the terminals of the circuit panel to to contact pads on the interposer. For example, some interposers used in microelectronic packaging have terminals in the form of exposed ends of pins or posts extending through the dielectric layer. In other applications, the terminals of an interposer can be exposed pads or portions of traces formed on a redistribution layer.

Despite considerable efforts devoted in the art heretofore to development of interposers and methods for fabricating such components, further improvement is desirable.

### BRIEF SUMMARY OF THE INVENTION

An aspect of the present disclosure relates to interconnection component including a low coefficient of thermal expansion (“CTE”) element having first and second opposed surfaces defining a thickness of the element, the element consisting essentially of a material having a first CTE of less than 10 parts per million per degree Celsius, the element having a plurality of contacts exposed at a first surface thereof. The interconnection component further includes a circuit panel including a dielectric element having first and second opposed surfaces defining a thickness of the circuit panel and a plurality of terminals exposed at the first surface thereof, the circuit panel having a thickness greater than 50% of the thickness of the low-CTE element. A bonding layer including a dielectric material bonds the second surfaces of the circuit panel and the low CTE element to one another. A plurality of metalized vias are further included and electrically connected with the terminals and the contacts, at least some vias extending through the bonding layer and through the thickness of the low CTE element.

The circuit panel can include a sheet-like dielectric element that defines at least one of the first and second surfaces of the circuit panel. The circuit panel can further include a plurality of sheet-like dielectric elements, wherein an outer one of the dielectric elements defines the first surface of the circuit panel, and wherein the circuit panel further includes routing circuitry extending within the dielectric elements to connect the metalized vias with the terminals. In an example, the circuit panel can have a thickness greater than 50 microns. The circuit panel can include epoxy having a stiffening filler such as an epoxy glass composite structure. In a further example, the circuit panel can include a stiffener therein including a sheet like island of glass fiber embedded therein. The stiffener can have a major surface having an area not greater than an area of a contact bearing surface of a microelectronic element to be mounted overlying the major surface of the stiffener. Such area of the stiffener can be greater than 50% of the area of the microelectronic element. The circuit panel can further include electrically conductive traces connecting the vias and the terminals or electrically conductive vias connecting the metalized vias, the traces and the terminals.

The low CTE element can consist essentially of silicon, glass, or ceramic material. In another example, the low CTE element can consist essentially of liquid crystal polymer. In another example, the interconnection the low CTE element can include silicon and can have a thickness of 100 microns or less.

The bonding layer can be a dielectric layer having a Young's modulus greater than 3 GPa. The bonding layer can consist essentially of inorganic dielectric material. In another example, the bonding layer can consist essentially of glass. Such glass can include a dopant. The bonding layer can be a polymeric material. The bonding layer can have a glass transition temperature greater than 125° C. In an example, the bonding layer can include at least one of epoxy or polyimide.

The interconnection component can further include masses of bond material attached to the first contacts. In an example, at least some of the contacts are exposed surfaces of the vias. In another example, at least some of the contacts include electrically conductive pads. The interconnection component can additionally or alternatively further include traces extending along the first surface between the vias and the pads.

The interconnection component can further include a cavity sized to accommodate a microelectronic element. The assembly can further include a second microelectronic element electrically connected with the first microelectronic element, the second microelectronic element extending at least partially into the cavity.

A microelectronic assembly can include an interconnection component as discussed above. The assembly can further comprise a microelectronic element having contacts on a contact-bearing face thereof facing the first surface of the low-CTE element, the contacts of the microelectronic element being joined to corresponding contacts on the low-CTE element through masses of bond material. In another example a microelectronic assembly can include an interconnection component as claimed as discussed above, along with first and second microelectronic elements. Each element can have contacts on a contact-bearing face thereof facing the first surface of the low CTE element, and the contacts of each of the first and second microelectronic elements can be joined to corresponding ones of the contacts through masses of bond material.

Another aspect of the present disclosure relates to an interconnection component. The interconnection component includes a low coefficient of thermal expansion (“CTE”) element having first and second opposed surfaces defining a thickness of the element, the element consisting essentially of a material having a first CTE of less than 10 parts per million per degree Celsius, the element having a first plurality of contacts exposed at the first surface thereof and a second plurality of contacts exposed at the second surface thereof. The interconnection component further includes a circuit panel having a dielectric element having first and second opposed surfaces defining a thickness of the circuit panel, routing circuitry embedded in the dielectric element, and a plurality of terminals exposed at the first surface thereof and electrically connected with the routing circuitry. The circuit panel has a thickness greater than 50% of the thickness of the low-CTE element. A bonding layer including a dielectric material bonds the second surfaces of the circuit panel and the low CTE element to one another. The interconnection component further includes a first plurality of metalized vias electrically connected with the first and second contacts, at least some first vias extending through the thickness of the low CTE element. The interconnection component further includes a second plurality of metalized vias, at least some of second vias extending through the bonding layer and the circuit panel and electrically connecting with the routing circuitry to electrically connect the second contacts with the terminals.

The circuit panel can include a plurality of sheet-like dielectric elements layered along the thickness thereof, and the routing circuitry can include a plurality of routing layers embedded among the plurality of sheet-like dielectric elements, the routing layers electrically connected with each other through the sheet-like elements. At least some of the second plurality of metalized vias can connect with a first one of the plurality of routing layers, and others of the second plurality of conductive vias can connect with a second one of the plurality of routing layers.

At least some of the contacts can be exposed surfaces of the vias. Additionally or alternatively, at least some of the contacts can include electrically conductive pads. The interconnection component can further include traces extending along the first surface between the vias and the pads.

A microelectronic assembly can include an interconnection component as discussed above along with a microelectronic element having contacts on a contact-bearing face thereof facing the first surface of the low-CTE element. The contacts of the microelectronic element can be joined to corresponding contacts on the low-CTE element through masses of bond material.

Another aspect of the present disclosure relates to a method of making an interconnection component. The method includes assembling a low coefficient of thermal expansion (“CTE”) element and a sheet-like dielectric element with a dielectric bonding layer between major surfaces of the low-CTE element and the dielectric element. The low-CTE element consists essentially of a material having a first CTE of less than 10 parts per million per degree Celsius. A plurality of metalized vias extend through the dielectric bonding layer and at least partially through the low-CTE element. The dielectric element has a CTE at least 50% greater than the first CTE and being greater than 10. The method further includes forming conductive elements and terminals overlying the dielectric element, and after the assembling step, forming contacts overlying the low-CTE element by depositing electrically conductive material to contact the metalized vias.

The dielectric element can include a plurality of sheet-like dielectric elements layered along the thickness thereof and routing circuitry having a plurality of routing layers embedded among the plurality of sheet-like dielectric elements. The routing layers can be electrically connected with each other through the sheet-like elements.

The step of forming conductive elements and terminals can include laminating a second sheet-like dielectric element to an exposed surface of the first dielectric element and forming the conductive elements extending through the first and second dielectric elements. The step of forming the contacts can further include forming electrically conductive traces and electrically conductive pads connected with the traces.

In an example of the method, the low-CTE element can have a thickness, and the metalized vias can be formed partially through the low-CTE element at a distance less than the thickness thereof. In such an example, the step of forming the contacts can include grinding the low CTE element after the assembling step to expose the metalized vias. The low-CTE element can have a thickness of at least 600 microns during the step of assembling, and the step of grinding can reduce the thickness of the low-CTE element to 100 microns or less. The step of forming the contacts can include forming electrically conductive traces and electrically conductive pads connected with the traces.

In an example, the step of assembling can include applying the dielectric bonding layer between the low-CTE element and the dielectric element and holding the low-CTE element and the dielectric element between first and second spaced-apart and parallel plates for a predetermined duration that includes curing of the bonding layer. The step of assembling can be carried out with the low-CTE element and the dielectric element in the form of one of a panel or a wafer, and the method can further include the step of segmenting the resulting assembly into a plurality of in-process units, at least one of which is further acted upon according to the steps of forming metalized vias, conductive elements and terminal, and contacts. The step of assembling can further include spinning a dielectric bonding material onto the low-CTE layer to form the dielectric bonding layer.

In another example, the method can further include a step of embedding sheet-like island of glass fiber in the dielectric layer to form a stiffener therein. The stiffener can have a major surface having an area not greater than an area of a contact-bearing surface of a microelectronic element to be mounted overlying the major surface of the stiffener. The area of the stiffener can be greater than 50% of the area of the microelectronic element.

Another aspect of the present disclosure relates to another method of making an interconnection component. The method includes assembling a low coefficient of thermal expansion (“CTE”) element with a dielectric element such that a dielectric bonding layer is positioned between major surfaces of the low-CTE element and the dielectric element. The low-CTE element consists essentially of a material having a first CTE of less than 10 parts per million per degree Celsius (“ppm/° C.”). The method further includes forming a plurality of metalized vias extending through the dielectric bonding layer and at least partially through the low-CTE element. The dielectric element has a CTE at least 50% greater than the first CTE and being greater than 10 ppm/° C. The method further includes forming conductive elements and terminals overlying the dielectric element and after the forming step, forming contacts overlying the low-CTE element by depositing electrically conductive material to contact the metalized vias. In an example, the step of forming the plurality of metalized vias can be carried out after the assembling step.

In another example, the dielectric element can include routing circuitry having pads exposed at the second surface thereof, and the step of forming the plurality of metalized vias can include forming a plurality of openings in the low-CTE element and through the bonding layer to expose the pads.

The step of forming the plurality of metalized vias can include depositing metal into the openings to contact the pads and to fill the openings.

Another aspect of the present disclosure relates to another method for making an interconnection component. The method includes assembling a low coefficient of thermal expansion (“CTE”) element with a sheet-like dielectric element and with a dielectric bonding layer positioned between major surfaces of the low-CTE element and the dielectric element. The low-CTE element consists essentially of a material having a first CTE of less than 10 parts per million per degree Celsius. A plurality of first metalized vias extend through the low-CTE element. The dielectric element having a CTE at least 50% greater than the first CTE and being greater than 10. The method further includes forming conductive elements and terminals overlying the dielectric element, and after the assembling step, forming second metalized vias through the bonding layer and the dielectric element. The second metalized vias being electrically connected between the first metalized vias and the conductive elements. The method can further include forming contacts overlying the low-CTE element by depositing electrically conductive material to contact the metalized vias. The step of forming the contacts can include grinding the low CTE element after the assembling step to expose the metalized vias.

The step of forming conductive elements and terminals can include laminating a second sheet-like dielectric element to an exposed surface of the first dielectric element, and forming the conductive elements extending through the first and second dielectric elements and further overlying the second dielectric element.

At least some of the second metalized vias can be directly electrically connected with the conductive elements overlying the first dielectric element, and others of the second metalized vias can be directly electrically connected with the conductive elements overlying the second dielectric element.

### BRIEF DESCRIPTION OF THE DRAWINGS

Various embodiments of the present invention will be described with reference to the appended drawings. It is appreciated that these drawings depict only some embodiments of the invention and are therefore not to be considered limiting of its scope.

FIG. 1 is a microelectronic assembly including an interconnection component according to one embodiment of the disclosure;

FIG. 2 is a microelectronic assembly including an interconnection component according to another embodiment of the disclosure;

FIG. 3 is a top plan view of the microelectronic assembly of FIG. 1;

FIG. 4 is a bottom plan view of the microelectronic assembly of FIG. 1;

FIG. 5 is a flowchart depicting a method for fabricating an interconnection component according to an embodiment of the present disclosure;

FIGS. 6-10 show an interconnection component during various stages of the fabrication method of FIG. 5;

FIGS. 11-13 show an interconnection component during various stages of an alternative fabrication method according to an embodiment of the present disclosure;

FIGS. 14-16 show an interconnection component during various stages of an alternative fabrication method according to an embodiment of the present disclosure;

FIG. 17 is an interconnection component during a stage of an alternative fabrication method according to an embodiment of the present disclosure;

FIG. 18 is a microelectronic assembly including an interconnection component according to another embodiment of the disclosure;

FIG. 19 is a microelectronic assembly including an interconnection component according to another embodiment of the present disclosure; and

FIG. 20 is a system that can include a microelectronic assembly having an interconnection component according to any of the embodiments herein.

### DETAILED DESCRIPTION

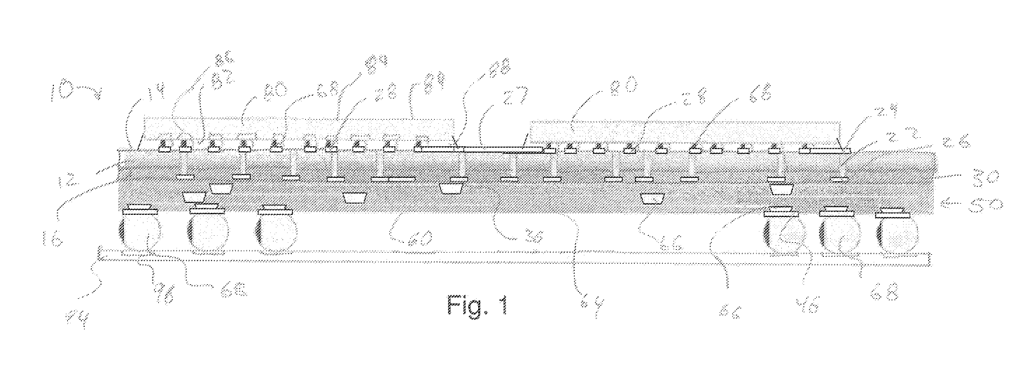

Turning now to the figures, where similar numeric references are used to refer to similar features, FIG. 1 shows a connection component 10 according to one embodiment of the present disclosure. In this embodiment, connection component includes a first material layer 12 bonded to a circuit layer 50 by a stiffening layer 30 positioned between the first material layer 12 and the circuit layer 50. Contact pads 28 can be exposed on an outside surface 14 of first material layer 12. Contact pads 28 are configured for connection to an external structure or component. Similarly, terminals 46 are exposed on an outside surface 60 of circuit layer 50. Terminals 46 are also configured for connection to an external structure or component. Contact pads 28 and terminals 46 are electrically connected with each other, such as in respective pairs of one contact pad 28 and one terminal 46, to provide a multilayer interposer structure 10.

First material layer 12 further includes an inside surface 16 that is generally parallel to outside surface 14 and spaced apart therefrom to define a thickness of first material layer 12. In an embodiment, first material layer 12 has a thickness of at least 5 microns. First material layer 12 can, in some embodiments, have a thickness of at least 50 microns and up to 300 microns, although a greater thickness is possible. In an embodiment, first material layer 12 has a thickness of about 100 microns or less. First material layer 12 can be of a dielectric material, such as a polymeric resin material, for example polyimide, glass, or fiber-reinforced epoxy. Alternatively, first material layer 12 can be of a semiconductor material such as silicon. First material layer can also be of a material having a low coefficient of thermal expansion (“CTE”), such as 10 parts per million per degree Celsius (“ppm/° C.”) or less. Materials of the types listed above can have such a CTE or can be made in certain variations or mixtures including one or more of the above materials, in addition to others, to achieve a desired CTE.

First material layer 12 includes a plurality of first metalized vias 22 therein extending substantially normal to both inside 16 and outside 14 surfaces through first material layer 12. First metalized vias 22 include inside ends 24 and outside ends 26 that are substantially flush respectively with inside 16 and outside 14 surfaces of first material layer 12. Both outside ends 26 and inside ends 24 can be substantially flush, or coplanar, with surfaces 14 or 16, respectively. In an embodiment, first metalized vias 22 are of a conductive material such as metal including copper, gold, nickel, aluminum, etc. Other conductive materials that can be used for first metalized vias 22 include conductive paste, or a sintered matrix including suspended conductive metal. First metalized vias 22 can be used to form electrical connections through first material layer 12 by connection of respective elements to inside 24 and outside 26 ends thereof. First material layer 12 holds the first metalized vias 22 in position and spaces apart the first metalized vias 22 from each other. As shown in the Figures, interconnection component 10 can be free from any electrically conductive interconnects running between the first metalized vias 22 or elsewhere in an at least partially lateral direction (parallel to the surfaces 14,16 of first material layer 12) within the material between the inside ends 24 and the outside ends 26.

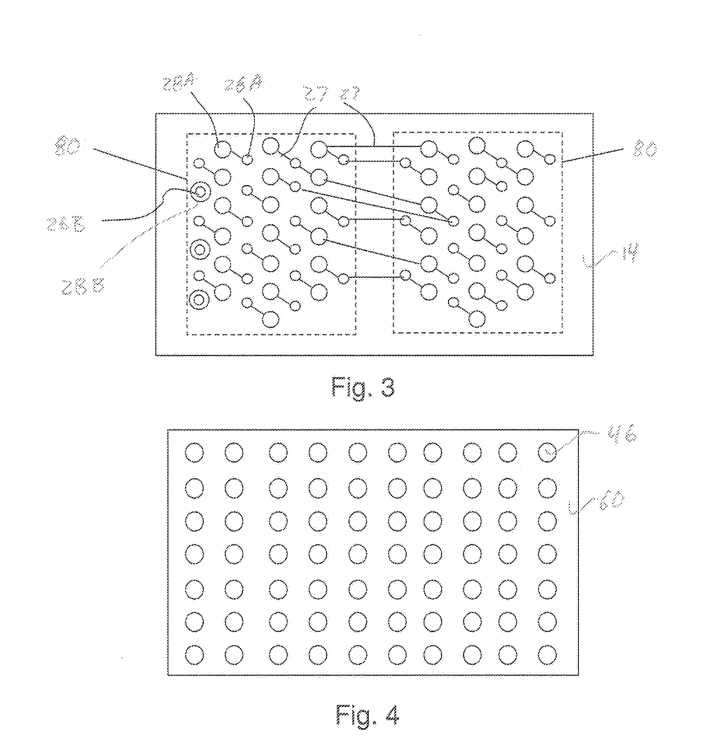

In an embodiment contact pads 28 can be offset in one or more lateral directions from respective first vias 22 as shown in FIG. 3. In such an embodiment, electrical interconnections such as traces or the like can be used to form connections running in a lateral direction between the outside end 26A of a via and a respective contact pad 28A. In another embodiment, contact pads 28B can be directly above a respective first via 22B and connect directly with the outside end 26B thereof. In other embodiments, some contact pads can be offset from their respective vias, with other contact pads directly overlying their respective vias. In another embodiment, outside ends 26 of at least some of the vias can be exposed at and substantially flush with outside surface 13 of first material layer 12 and can form wettable contacts for connection with an external component.

Stiffening layer 30 overlies inside surface 16 of first material layer and is bonded thereto. Stiffening layer 30 can be made from a material having a Young's modulus of less than about 9 GPa or having a glass transition temperature (“Tg”) of at least 110° C. Such a material can be polymeric or of a polymeric matrix with stiffening particles, such as glass, suspended therein. In an embodiment, stiffening layer 30 can be made from a material similar to that which is used to form underfill layers, such as between microelectronic components bonded with solder balls or the like. Stiffening layer 30 further overlies inside surface 56 of circuit layer 50 and extends therealong such that a thickness of stiffening layer 30 spaces apart first material layer 12 and circuit layer 50. In an embodiment the thickness of stiffening layer can be at least about 50% of the thickness of first material layer. In an embodiment, stiffening layer 30 can cover the entirety of inside surface 16 of first material layer 12. In other embodiments, stiffening layer 30 can cover an area smaller than that of surface 16. In such embodiments, stiffening layer 30 can be in one or more portions that underlie a microelectronic element 80 and are of an area at least 50% as large as that of the corresponding microelectronic element 80.

In the embodiment shown in FIG. 1, first vias 22 further pass through stiffening layer 30 and are exposed at second surface 34 thereof. In this embodiment, an electrical connection can be made to contacts 28 through first material layer 12 and stiffening layer 30 by an element overlying second surface 34 and contacting vias 22.

Circuit layer 50 electrically interconnects respective pairs of first metalized vias 22 and terminals 46 such that an electronic interconnection can be made between a structure connected with a selected contact pad 28 and another structure connected with an associated terminal 46 with an associated first metalized via 22 forming at least part of that interconnection. The electrical interconnection can further be achieved through circuit layer 50 by redistribution circuitry in the form of, for example, traces 64 and vias 66 embedded in circuit layer 50. In an embodiment, traces 64 can extend in lateral directions through circuit layer 50, which can be carried out through a number of different layers distributed among the thickness of circuit layer 50. Vias 66 can extending between traces 64 in different layers to form interconnection through the thickness of circuit layer 50. Circuit layer 50 can be primarily of a dielectric material and can have a thickness to support the desired routing circuitry therethrough. In an example one or more sheet-like dielectric layers can overlie each other to comprise circuit layer 50. In such an example, the individual layers of traces 64 can be formed over or embedded within respective dielectric layers with vias 66 extending through the dielectric layers to connect with traces 64 in another dielectric layer. In the example shown in FIG. 1, circuit layer 50 includes three layers of traces 64, but in other embodiments more or fewer layers can be used.

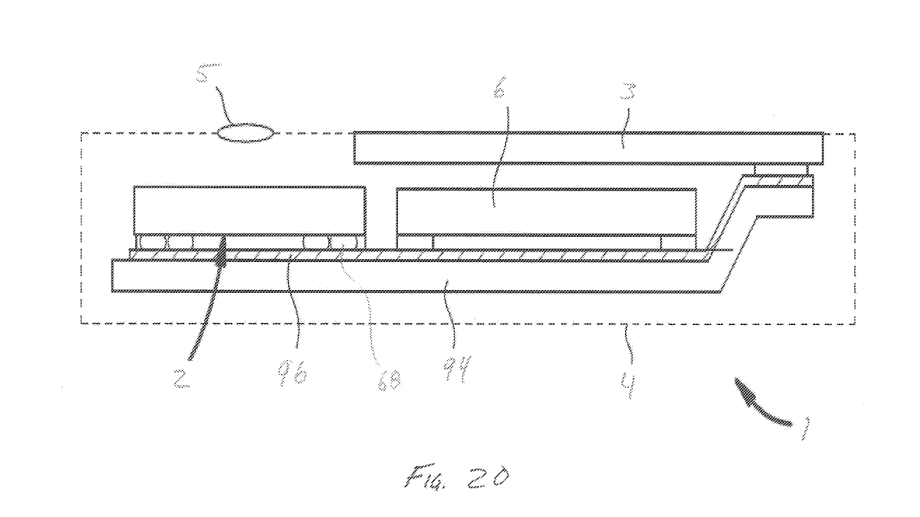

As shown, first circuit layer 50 has an inside surface 54 that faces first material layer 12 and is bonded to stiffening layer 30. Similarly, circuit layer 50 has an outside surface 60 that terminals 46 overlie. Terminals 46 can be joined with vias 66 or with traces 64, depending on the layering arrangement of circuit layer 50. Similarly, some of either the traces 64 or vias 66, depending on the particular routing configuration, can connect with respective ones of the first metalized vias 22 at the inside ends 24 thereof. In an embodiment, such as that shown in FIG. 19, circuit layer 50 can have a stiffener 74 embedded therein. Stiffener 74 can be in the form of a separate sheet-like material structure that is embedded within circuit layer. Such material can have a greater stiffness that the material that comprises circuit layer 50. Stiffener 74 can alternatively include, for example, a region of circuit layer 50 that includes reinforcing fibers embedded therein. In an embodiment where circuit layer 50 is made from a polymeric material, such fibers can be, for example, glass fibers that are embedded within the polymeric material to form a composite structure of glass fibers suspended within the polymeric material of circuit layer 50. Stiffener 74 can be positioned within the area or areas of the one or more microelectronic elements 80 that can be joined with connection component 10. Further stiffener 74 can extend in lateral directions parallel to surface 54, for example, to define an area that is less than or equal to that of a corresponding microelectronic element 80.

As shown in FIG. 1, wettable contacts in the form of contact pads 28 or terminals 46 can be exposed at outside surfaces 14 and 60, respectively. Additionally, wettable metal layers or structures can be added to interconnection component 10 that can be wettable contacts for connection to other microelectronic components. Such wettable metal layers or structures can be made from nickel or Ni—Au, or organic solderable preservative (“OSP”). Such wettable contacts can overlie and be electrically connected with outside ends 26 of first metallized vias 22 or with features of the routing circuitry of circuit layer 50. The contact pads 28 and terminals 46 can be spatially positioned respectively over outside surfaces 14 and 60 in an array that corresponds to the conductive vias 22 or routing features (such as traces 64 or vias 66) to which they are connected. Contact pads 28 and terminals 46 can vary in size to accommodate the size, or pitch, of an array in which they are positioned, without contacting each other, or to achieve the desired electrical connection with one or more external structures. Contact pads and terminals 46 can be of the same or of a different conductive material than vias 22 our routing circuitry. Contact pads 28 or terminals 46 can be positioned respectively on or in first material layer 12 or circuit layer 50 such that they are displaced in one or more lateral directions from the first vias 22 to which they are electrically connected such to form redistribution circuitry.

The wettable contacts, such as contact pads 28 and terminals 46 (or other suitable structures) can allow connection component 10 to connect to or between microelectronic components that respectively overlie outside surfaces 14 and 60 of component 10. As shown in FIG. 1, connection component 10 can be used to connect one or more microelectronic elements 80 overlying outside surface 14 to an external circuit panel 94 that outside surface 60 overlies. In an embodiment, connection component 10 can be used to form such a connection between two microelectronic components that have contacts arranged thereon in different respective pitches. As shown in FIG. 1, microelectronic elements 80 each have a front surface 82 with contacts 86 exposed thereon. A back surface 82 is spaced apart from and parallel to front surface 82. In the embodiment shown, microelectronic element is mounted to outside surface 14 as a flip-chip, having front surface 82 facing outside surface 14 and having contacts bonded to contacts 28 using solder balls 68 with an underfill 88 between microelectronic element 80 and surface 14 and surrounding solder balls 68. Connection component 10 (and, thus, microelectronic element 80) is mounted to external circuit panel 94 by joining terminals 46 to circuit contacts 96 using solder balls 68.

As shown, contacts 86 of microelectronic element 80 are generally spaced apart in an array having a pitch that is smaller than that of the circuit contacts 96 on circuit panel 94. Accordingly, contact pads 28 are arranged in an array configuration, including a pitch thereof, that substantially matches the array configuration and pitch of the microelectronic element 80 contacts 86. Similarly, terminals 46 are arranged in an array configuration, including a pitch thereof, that substantially matches the array configuration and pitch of circuit contacts 96. Arrays of contacts can be in any desired configuration, such as in a grid having a number of rows and columns. The pitch of an array can be measured based on a uniform spacing of contacts in one or more directions. Alternatively, the pitch can be designated as an average, maximum, or minimum distance between contacts in an array. In other embodiments, the pitch of contact pads 28 and terminals 46 can be substantially the same, or the pitch of contact pads 28 can be greater than the pitch of terminals 46. In an embodiment, contact pads 28 can be in an array having a first pitch, and terminals 46 can have a second pitch that is between 1 and 5 times the size of first pitch. In another embodiment, the second pitch can be about 2 times the size of first pitch. Additional traces 27 that extend along outside surface 14 between contact pads 28 associated with different microelectronic elements 80 to provide a connection between the microelectronic elements 80.

First metalized vias 22 and routing circuitry, including traces 64 and vias 66 in circuit layer 50 electrically connect corresponding contact pads 28 and terminals 46 both in a direction through the thickness of connection component 10 and in any lateral directions in which the contact pads 28 and terminals 46 are offset from each other. First metalized vias 22, as discussed above, can be positioned such that contact pads 28 directly overlie them or are spaced apart in one or more lateral directions therefrom. Accordingly, first metalized vias 22 can be in the same spatial configuration as contact pads 28 or in a different spatial configuration. With respect to pitch, first metalized vias 22 can be the same or near the same pitch as contact pads 28. In other embodiments, first metalized vias can be of a pitch greater than the pitch of contact pads 28, such as between the pitch of contact pads 28 and terminals 46 or near the pitch of terminals 46. Routing circuitry, as discussed above, can be structured to connect first metalized vias 22 to a terminal 46 that is displaced in one or more lateral directions therefrom. Accordingly, in an embodiment where, for example, the pitch of first metalized vias 22 is the same as or only somewhat larger than that of contact pads 28, the routing circuitry within circuit layer 50 can connect between intermediate contacts 36 or inside ends 24 of first metalized vias 22 and terminals 46 to achieve the desired connection and to compensate for the difference in pitch. Similarly, routing circuitry can compensate for differences in connection configuration, including the arrangement of respective contacts or to connect a contact pad 28 configuration in multiple arrays, such as shown in FIG. 3, to a terminal 46 configuration in a single array (as shown in FIG. 4). In some embodiments, first material layer 12 can provide a higher density routing (such as by first metalized vias 22) than circuit layer 50 can provide. Accordingly, in such embodiments, the pitch of first metalized vias 22 can be approximately the same as contact pads 28 with the routing circuitry achieving most of the lateral interconnection to terminals 46, which can have a pitch of, for example, between 2 and 5 times that of contact pads 28.

The layered arrangement of structures in connection component 10, including first material layer 12 bonded to circuit layer 50 by stiffening layer 30 can provide a more compact interconnection component than other embodiments where an interposer layer similar to first material layer 12 by itself is joined to a separate circuit panel by solder balls. Further interconnection component 10 can be easier to manufacture and can be made by a process that results in fewer failures than such other embodiments. The presence of stiffening layer 30 between first material layer 12 and circuit layer 50 can reduce warpage throughout the structure of interconnection component 10, both during manufacturing and during usage conditions. This can be attributed to the high Young's modulus and/or high Tg of stiffening layer, as described above. In an example, a CTE mismatch between first material layer 12 and circuit layer 50 (such as in which the CTE of first material layer 12 is lower than that of circuit layer 50) could create a stress within the structure of interconnection component 10 that could cause warping or failure in the absence of stiffening layer 30. In such conditions, stiffening layer 30 can withstand such internal stresses to prevent warping or failure.

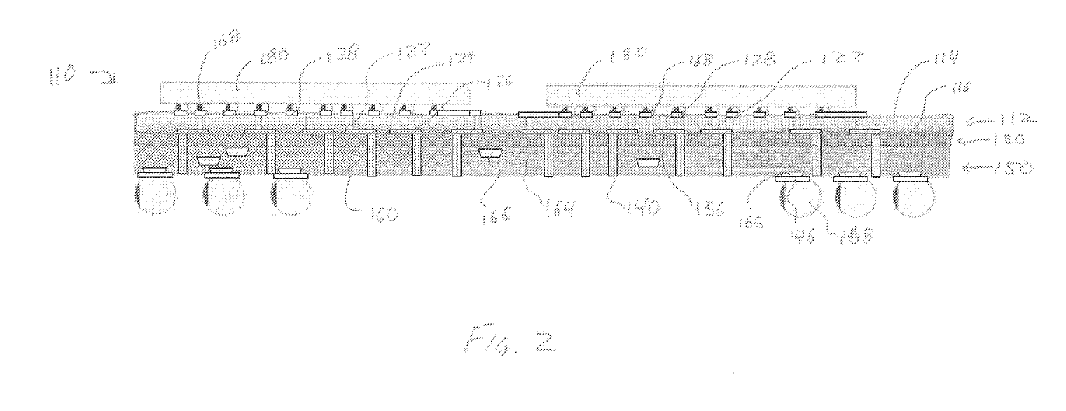

FIG. 2 shows an alternative embodiment of an interconnection component 110. In this embodiment, first metalized vias 122 extend substantially through first material layer 112 but do not extend through stiffening layer 130. Further, intermediate contacts 136 can be exposed at inside surface 116 of first material layer 112 or at another location at the interface between first material layer 112 and stiffening layer 130. As shown, intermediate contacts 136 can have traces or other routing features integral therewith to redistribute the contact configuration provided by first metalized vias 122. Second metalized vias 140 extend through circuit layer 150 and through stiffening layer 130 to connect with intermediate contacts 136 to provide at least a portion of the connection between first metalized vias 122 and terminals 146. In the embodiment shown, second metalized vias 140 connect with predetermined ones of the traces 164 within circuit layer 150 at a point between inside ends 144 and outside ends 142 thereof. By connecting to an intermediate contact 127 at the inside end 144 thereof and a trace 164 remote from the intermediate contact 127 an electrical connection can be achieved through stiffening layer 30 to the routing circuitry within circuit layer 150 to connect with a respective terminal 146. In an alternative embodiment, second metalized vias 140 can connect directly with at least some of terminals 146 through stiffening layer 130 and circuit layer 150.

A further alternative embodiment of an interconnection component 210 is shown in FIG. 18 in which a cavity 272 is formed in interconnection component 210 that is open to outside surface 214 of first material layer 212. In the embodiment shown, cavity 272 extends through first material layer 212, through stiffening layer 230 and partially though circuit layer 250, although other arrangements are possible, including those where the cavity only partially extends through the stiffening layer or only partially through the first material layer. Cavity 272 can be used to receive a lower microelectronic element 280B that is affixed at a front face thereof to a corresponding front face of microelectronic element 280A using, for example solder balls. Microelectronic element 280A is then mounted on first material layer 212 as described above with respect to FIG. 1, with microelectronic contacts 286 joined to contact pads 228 by solder balls 268. The arrangement of contact pads 228 and first metalized vias 222 can be adjusted to extend in the area surrounding cavity 272.

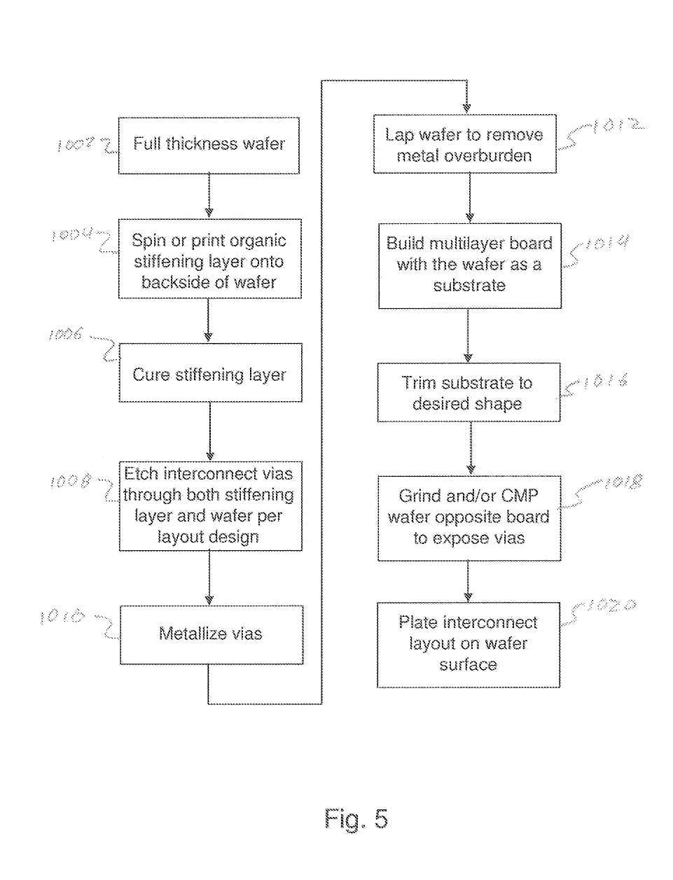

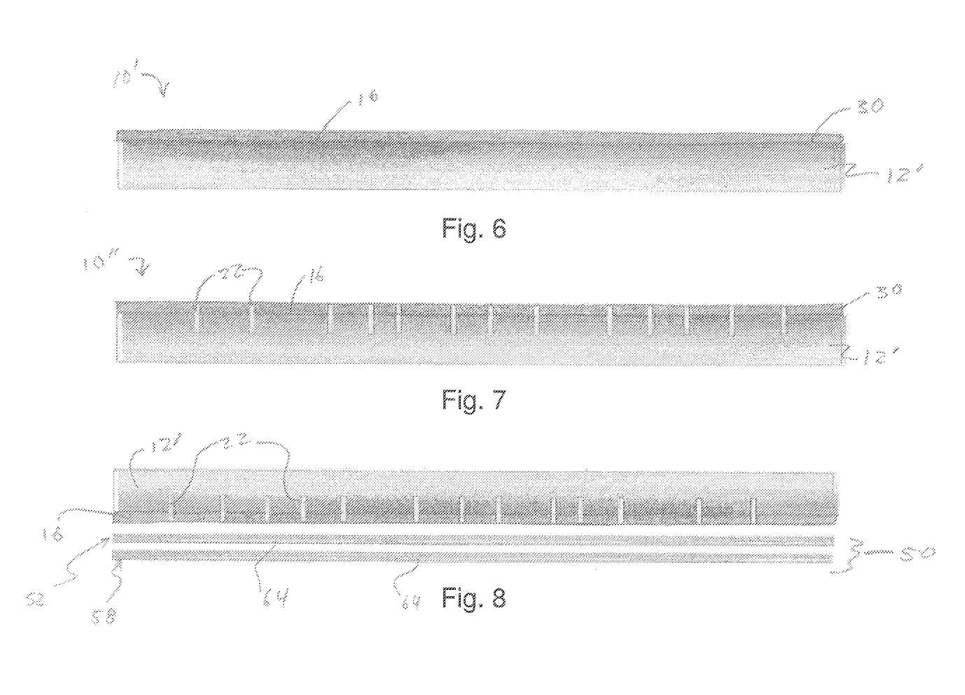

Various steps in an exemplary method for making an interconnection component 10 similar to the embodiment of FIG. 1 are shown in FIG. 5. Further, the interconnection component is shown during various stages of such a method in FIGS. 6-10. In step 1002 (FIG. 5), a first material substrate 12′ (FIG. 6) is provided to be used to form first material layer 12 for interconnection component 10. First material substrate 12′ can have different dimensions, including lateral directions and a thickness, than what is intended for first material layer 12. Such dimensions are altered to achieve the desired final dimensions in further steps described below. In particular, the thickness of first material substrate 12′ can be about three times the intended final thickness of first material layer 12 and in one embodiment up to six times the intended final thickness. For example, first material substrate 12′ can have a thickness of, for example, 600 microns, and can be subsequently ground down, as discussed below, to achieve a desired thickness for first material layer 12 of, for example, 100 microns. This increased thickness can make first material substrate 12′ less prone to breaking during handling and formation of first metalized vias 22, discussed below. Further, first material substrate 12′ can be in the form of a wafer or panel that is sized such that a plurality of in-process unites 10′ (FIG. 5) can be formed simultaneously. In such an example, the wafer or panel can be segmented to form such a plurality of in-process units 10′ before grinding or other subsequent steps, as discussed below.

In step 1004 (FIG. 5), stiffening layer 30 is formed by is spinning or printing the material used to form stiffening layer 30 onto inside surface 16 of first material substrate 12′ in such a manner that the material is built up onto surface 16 to a sufficient thickness for stiffening layer 30. In step 1006, the material for stiffening layer 30 is cured. This can be done by providing adequate time to allow for chemical curing in embodiments where stiffening layer 30 is formed by a self-curing resin. In other embodiments, curing can be achieved using heat or exposure to UV light. The step of curing can be carried out with in-process unit 10′ pressed or otherwise positioned between two substantially parallel, flat plates to ensure a planar outer surface for stiffening layer 30 and for first material substrate 12′. This can result in the in-process unit 10′ shown in FIG. 6 wherein stiffening layer 30 is shown having been formed on first material substrate 12′.

In step 1008 (FIG. 5), vias 22′ in the form of substantially cylindrical openings are formed through stiffening layer 30 and at least partially through first material substrate 12′. In the embodiment described above, in which first material substrate 12′ has a thickness greater than the desired thickness for first material layer 12, vias 22′ can extend only partially through first material substrate 12′ such as to a depth just greater than the desired thickness of first material layer 12. The formation of the vias 22′ can be carried out by etching (such as chemical or laser etching) or by a mechanical process such as drilling or the like. In step 1010, the vias are filled with conductive material to form first metalized vias 22, as shown in FIG. 7. The vias can be filled by a process such as plating or by mechanically forcing a metallic paste or the like into the openings. The inside surface 16 of first material substrate 12′ can then be lapped or otherwise processed in step 1012 (FIG. 5) to remove any excess material thereon that results as a by-product from via metallization.

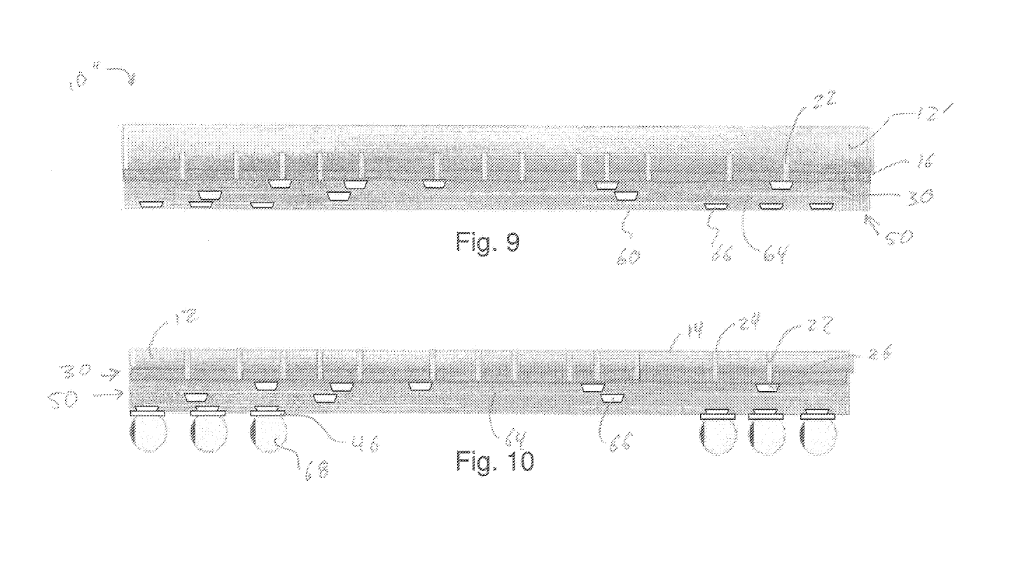

In step 2014 (FIG. 5) and as shown in FIG. 8, circuit layer 50 can then be added to the in-process unit 10′. As shown, circuit layer 50 can be added in successive layers, such as layers 52 and 58, of dielectric material with traces 64 and vias 66 embedded therein to form the routing circuitry through circuit layer 50, as discussed above. In an embodiment, dielectric layer 52 can be formed, such as by spinning or printing, over stiffening layer 30. After curing of dielectric layer 52, conductive vias 66 can be formed through layer 52 and in contact with inside ends 24 of first metalized vias 22 or with intermediate contacts 27 (shown in FIG. 1). Traces 66 can then be formed along a then-exposed surface of dielectric layer 52 by plating and etching or by printing or the like. A second dielectric layer 58 can then be formed over dielectric layer 52 and over the associated traces 64. Additional vias can be formed through layer 58 to connect with the traces 66 that were covered thereby. Further, additional layers having traces 64 and vias 66 associated therewith can be formed, as desired in a similar manner. Other methods for forming layers to make circuit layer 50 are possible, including forming a first set of traces 64 prior to forming the first dielectric layer. An example of a resulting in-process unit 10″ is shown in FIG. 9. The vias 64 can connect with terminals 46 that are subsequently formed on outside surface 60 either directly or by additional traces along the outside surface 60 of circuit layer 50. In another embodiment, vias 66 that are exposed on surface 60 can be used as terminals 46.

In subsequent steps, the in-process unit 10″ can be trimmed to the desired lateral dimensions and shape (step 2016 in FIG. 5), such as square, round or the like. Wafer 10′ is then ground down or subjected to a chemical/mechanical polishing (“CMP”) process to form first material layer 12 of the desired thickness and to expose outside ends 26 of first metalized vias 22 on newly-formed outside surface 14. An example of an interconnection component 10 resulting from these steps is shown in FIG. 10 with solder balls 68 joined with terminals 46. In step 1020, an interconnect layout including contact pads 28 and, optionally traces 27, can be formed along outside surface 14 of first material layer 12. The resulting interconnection component 10 can then be assembled with one or more microelectronic elements 80 and an external circuit panel 90 to form an assembly.

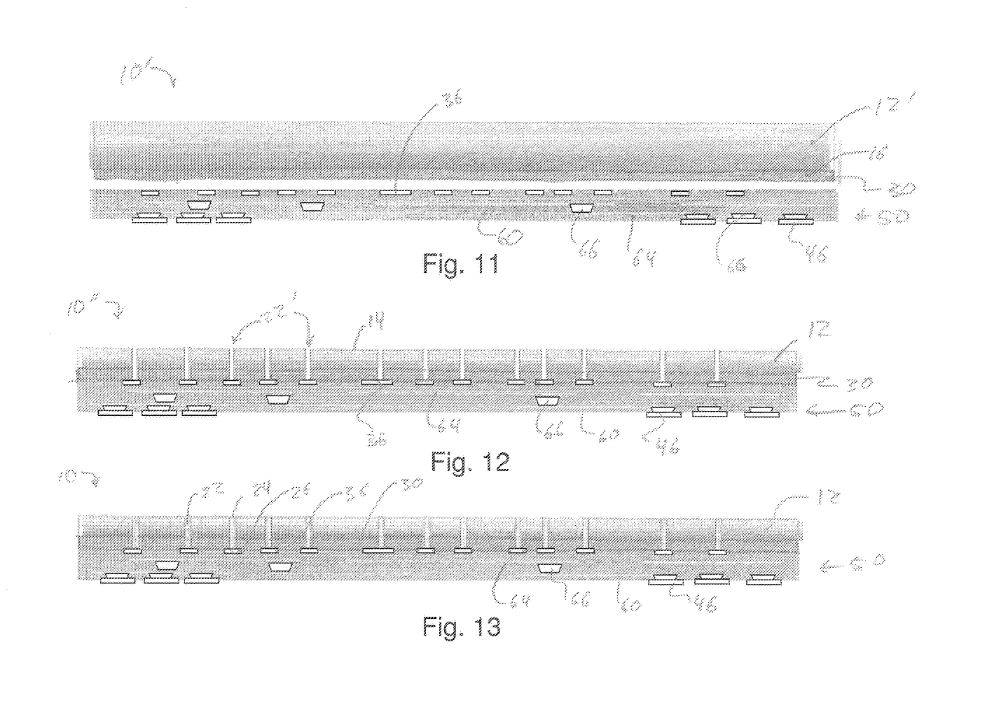

Interconnection component 10 is shown in FIGS. 11-13 in various stages of an alternative fabrication method embodiment. As shown in FIG. 11, an in-process unit 10′ has been fabricated according to steps 1002-1006, as discussed above. Then, circuit layer 50 is formed on in-process unit 10′ with vias 66 (or intermediate contacts 36 connected with traces 66, depending on the method of circuit layer formation) in contact with portions of stiffening layer 30. Circuit layer 50 can be formed as discussed above with respect to step 1014 in FIG. 5. Subsequently, first material substrate 12′ is then ground down and/or subjected to a CMP process to achieve the desired thickness and planarity thereof for first material layer 12. Vias 22′ are then formed through first material layer 12 and through stiffening layer 30 to expose vias 66 (or intermediate contacts 36) at outside surface 14 of first material layer 12. The vias 22′ can be formed according to the process described above with respect to step 1008 in FIG. 5. The resulting in-process unit 10″ is shown in FIG. 11. The vias 22′ are then metalized, as discussed above with respect to step 1010 in FIG. 5. By this process, first metalized vias 22 are formed in contact with vias 66 (or intermediate contacts 36) and with outside ends 26 thereof exposed at surface 14, as shown in FIG. 13, for connection with an external structure or with contact pads 28, as discussed above.

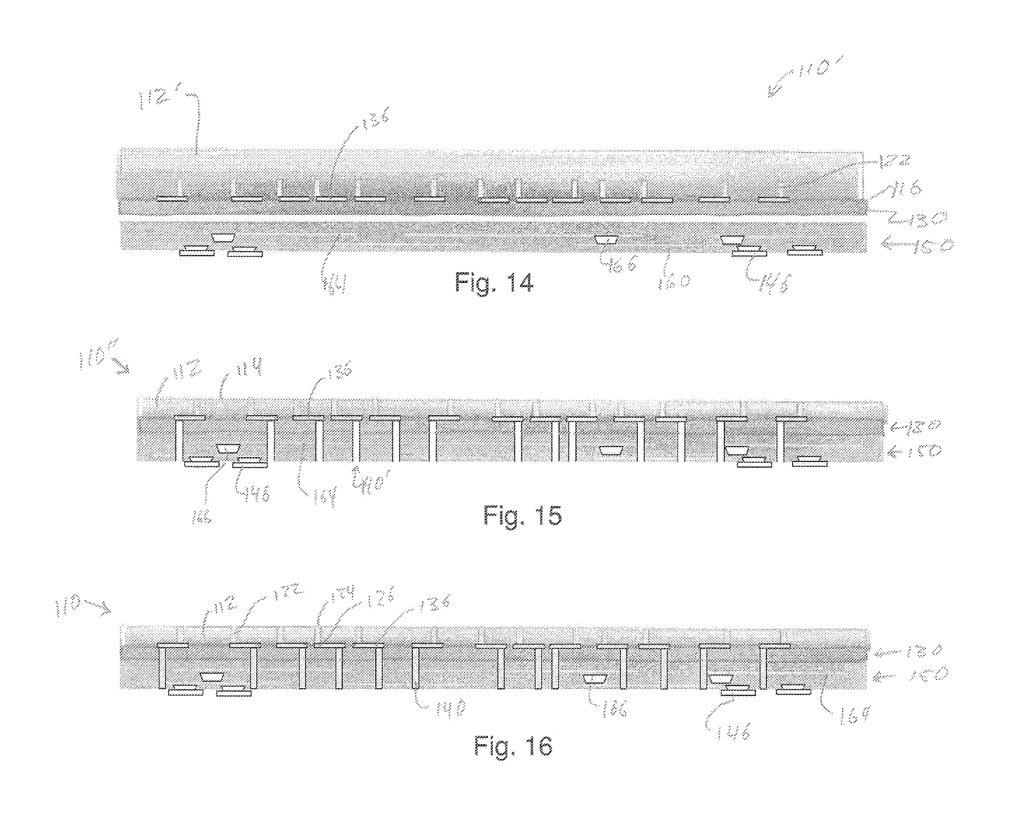

An interconnection component 110 during further alternative fabrication method steps is shown in FIGS. 14-16. In FIG. 14, and in-process unit 110′ is shown in the form of a first material substrate 112′ having first metalized vias 122 formed partially therethrough to a depth at least equal to a desired thickness for the finished first material layer 112 to be formed therefrom. Intermediate contacts 136 are formed in contact with inside ends 124 of first metalized vias 122 and can overlie inside surface 116 or be embedded in first material substrate 112′ with portions thereof exposed at inside surface 116. In process unit 110′ also has stiffening layer 130 formed over surface 116, which can be done according to the discussion of step 1004 in FIG. 5, above. Circuit layer 150 (FIG. 14) is then formed on in-process unit 110′ over stiffening layer 130. This can be done according to the above discussion of step 1014 in FIG. 5. As shown in FIG. 15, vias 140′ are then formed through circuit layer 150 and through stiffening layer 130 to expose intermediate contacts 136 at surface 160 of circuit layer 150. The vias 140′ are formed according to the discussion of the formation of vias above with respect to step 1008 in FIG. 5. Vias 140′ can be formed through or intersecting with selected ones of the traces 164 in circuit layer 150 such that when vias are metalized, as shown in FIG. 16 and done according to the discussion of step 1010 in FIG. 5, above, they can form portions of electrical connections between vias 122 and the routing circuitry of circuit layer 150. Such routing circuitry includes the traces 164 and vias 166 that connect with terminals 146 which can be formed over surface 160, as discussed above to form the interconnection component 110 of FIG. 2.

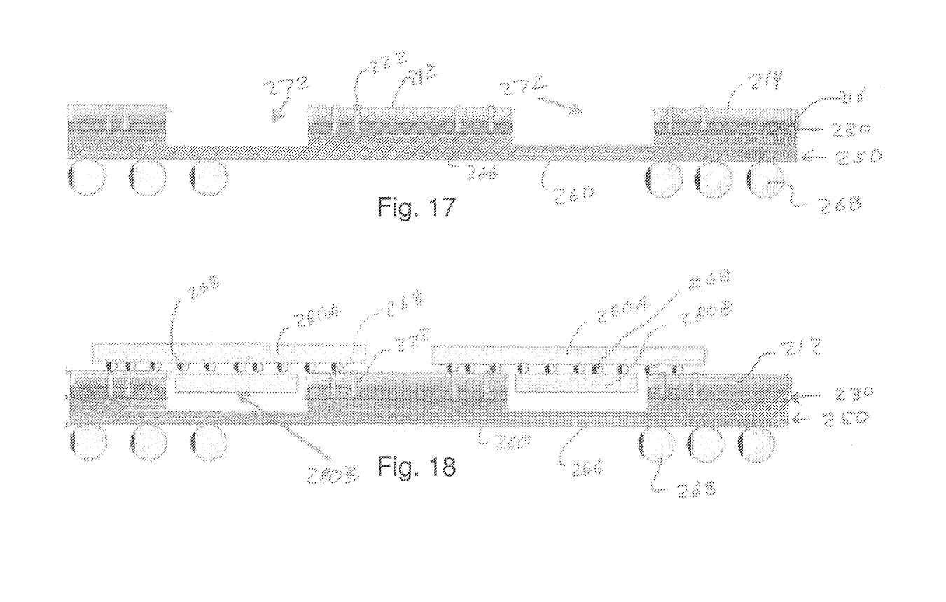

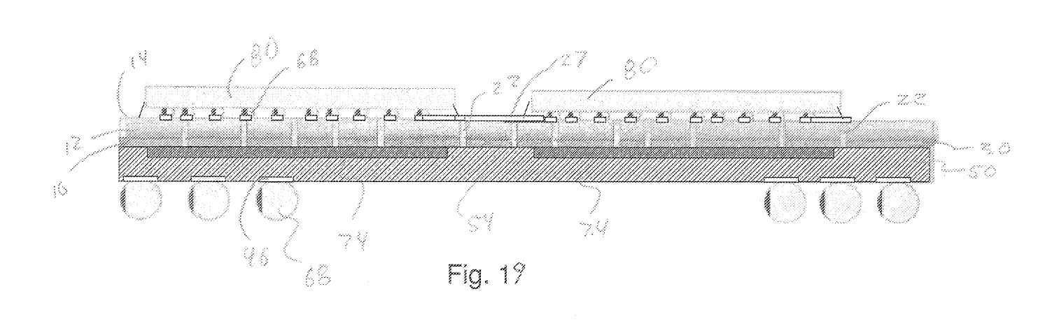

The method step shown in FIG. 17 can be added to any of the above-discussed fabrication methods. Specifically, any of the interconnection components can be formed having vias 222 along with routing circuitry in circuit layer 250 properly positioned to accommodate the formation of cavity, such as cavity 272 formed in interconnection component 210 shown in FIG. 17. Cavity 272 can be formed by chemical or mechanical etching or by grinding, milling, or sawing. As discussed above, cavity 272 can be sized to accept a microelectronic component, such as a microelectronic element 280B therein, as shown in FIG. 18.

Various embodiments of the connection components described herein can be used in connection with various diverse electronic systems. The interconnection components described above can be utilized in construction of diverse electronic systems, as shown in FIG. 20. For example, a system 1 in accordance with a further embodiment of the invention can include a microelectronic assembly 2, being a unit formed by assembly of a microelectronic element 80 with an interconnection component 10, similar to the microelectronic assembly of a microelectronic element 80 and interconnection component 10 as shown in either of FIG. 1, 2, 18, or 19. The embodiment shown, as well as other variations of the interconnection component or assemblies thereof, as described above can be used in conjunction with other electronic components 6 and 3. In the example depicted, component 6 can be a semiconductor chip or package or other assembly including a semiconductor chip, whereas component 3 is a display screen, but any other components can be used. Of course, although only two additional components are depicted in FIG. 20 for clarity of illustration, the system may include any number of such components. In a further variant, any number of microelectronic assemblies including a microelectronic element and an interconnection component can be used. The microelectronic assembly and components 6 and 3 are mounted in a common housing 4, schematically depicted in broken lines, and are electrically interconnected with one another as necessary to form the desired circuit. In the exemplary system shown, the system includes a circuit panel 94 such as a flexible printed circuit board, and the circuit panel includes numerous conductors 96 interconnecting the components with one another. However, this is merely exemplary; any suitable structure for making electrical connections can be used, including a number of traces that can be connected to or integral with contact pads or the like. Further, circuit panel 94 can connect to interconnection component 10 using solder balls 68 or the like. The housing 4 is depicted as a portable housing of the type usable, for example, in a cellular telephone or personal digital assistant, and screen 3 is exposed at the surface of the housing. Where system 1 includes a light-sensitive element such as an imaging chip, a lens 5 or other optical device also may be provided for routing light to the structure. Again, the simplified system 1 shown in FIG. 20 is merely exemplary; other systems, including systems commonly regarded as fixed structures, such as desktop computers, routers and the like can be made using the structures discussed above.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. An interconnection component, comprising:
a low-coefficient of thermal expansion (“CTE”) element having first and second opposed surfaces defining a thickness of the element, the element consisting essentially of a material having a first CTE of less than 10 parts per million per degree Celsius, the element having a plurality of contacts exposed at a first surface thereof;
a circuit panel including a dielectric element having first and second opposed surfaces defining a thickness of the circuit panel and a plurality of terminals exposed at the first surface thereof, the circuit panel having a thickness greater than 50% of the thickness of the low-CTE element;
a bonding layer including a dielectric material bonding the second surfaces of the circuit panel and the low-CTE element to one another; and
a plurality of metalized vias electrically connected with the terminals and the contacts, at least some vias extending through the bonding layer and through the thickness of the low-CTE element.

2. The interconnection component of claim 1, wherein the circuit panel includes a sheet-like dielectric element that defines at least one of the first and second surfaces of the circuit panel.

3. The interconnection component of claim 2, wherein the circuit panel includes a plurality of sheet-like dielectric elements, wherein an outer one of the dielectric elements defines the first surface of the circuit panel, and wherein the circuit panel further includes routing circuitry extending within the dielectric elements to connect the metalized vias with the terminals.

4. The interconnection component of claim 1, wherein the low-CTE element consists essentially of silicon, glass, or ceramic material.

5. The interconnection component of claim 1, wherein the low-CTE element consists essentially of liquid crystal polymer.

6. The interconnection component of claim 1, wherein the bonding layer is a dielectric layer having a Young's modulus greater than 3 GPa.

7. The interconnection component of claim 6, wherein the bonding layer consists essentially of inorganic dielectric material.

8. The interconnection component of claim 7, wherein the bonding layer consists essentially of glass.

9. The interconnection component of claim 7, wherein the glass includes a dopant.

10. The interconnection component of claim 6, wherein the bonding layer is a polymeric material.

11. The interconnection component of claim 10, wherein the bonding layer has a glass transition temperature greater than 125° C.

12. The interconnection component of claim 11, wherein the bonding layer includes at least one of epoxy or polyimide.

13. The interconnection component of claim 4, wherein the low-CTE element includes silicon and has a thickness of 100 microns or less.

14. The interconnection component of claim 13, wherein the circuit panel has a thickness greater than 50 microns.

15. The interconnection component of claim 1, wherein the circuit panel includes epoxy having a stiffening filler.

16. The interconnection component of claim 1, wherein the circuit panel has an epoxy-glass composite structure.

17. The interconnection component of claim 16, wherein the circuit panel includes a stiffener therein including a sheet-like island of glass fiber embedded therein, the stiffener having a major surface having an area not greater than an area of a contact-bearing surface of a microelectronic element to be mounted overlying the major surface of the stiffener, the area of the stiffener being greater than 50% of the area of the microelectronic element.

18. The interconnection component of claim 1, further comprising masses of bond material attached to the first contacts.

19. The interconnection component of claim 1, wherein at least some of the contacts are exposed surfaces of the vias.

20. The interconnection component of claim 1, wherein the at least some of the contacts include electrically conductive pads.

21. The interconnection component of claim 20, further comprising traces extending along the first surface between the vias and the pads.

22. The interconnection component of claim 1, wherein the circuit panel further includes electrically conductive traces connecting the vias and the terminals.

23. The interconnection component of claim 22, wherein the circuit panel further includes electrically conductive vias connecting the metalized vias, the traces and the terminals.

24. A microelectronic assembly including an interconnection component as claimed in claim 1, further comprising a microelectronic element having contacts on a contact-bearing face thereof facing the first surface of the low-CTE element, the contacts of the microelectronic element being joined to corresponding contacts on the low-CTE element through masses of bond material.

25. A microelectronic assembly including an interconnection component as claimed in claim 1, further comprising first and second microelectronic elements, each having contacts on a contact-bearing face thereof facing the first surface of the low-CTE element, the contacts of each of the first and second microelectronic elements being joined to corresponding ones of the contacts through masses of bond material.

26. The interconnection component as claimed in claim 1, wherein the masses of bond material include a bond metal.

27. The interconnection component as claimed in claim 1, further comprising a cavity sized to accommodate a microelectronic element.

28. The microelectronic assembly as claimed in claim 24, wherein the interconnection component includes a cavity, the assembly further comprising a second microelectronic element electrically connected with the first microelectronic element, the second microelectronic element extending at least partially into the cavity.

29. An interconnection component, comprising:
a low-coefficient of thermal expansion (“CTE”) element having first and second opposed surfaces defining a thickness of the element, the element consisting essentially of a material having a first CTE of less than 10 parts per million per degree Celsius, the element having a first plurality of contacts exposed at the first surface thereof and a second plurality of contacts exposed at the second surface thereof;
a circuit panel including a dielectric element having first and second opposed surfaces defining a thickness of the circuit panel, routing circuitry embedded in the dielectric element, and a plurality of terminals exposed at the first surface thereof and electrically connected with the routing circuitry, the circuit panel having a thickness greater than 50% of the thickness of the low-CTE element;
a bonding layer including a dielectric material bonding the second surfaces of the circuit panel and the low-CTE element to one another;
a first plurality of metalized vias electrically connected with the first and second contacts, at least some first vias extending through the thickness of the low-CTE element; and
a second plurality of metalized vias, at least some of second vias extending through the bonding layer and the circuit panel and electrically connecting with the routing circuitry to electrically connect the second contacts with the terminals.

30. The interconnection component of claim 29, wherein the circuit panel includes a plurality of sheet-like dielectric elements layered along the thickness thereof, and wherein the routing circuitry includes a plurality of routing layers embedded among the plurality of sheet-like dielectric elements, the routing layers electrically connected with each other through the sheet-like elements.

31. The interconnection component of claim 30, wherein at least some of the second plurality of metalized vias connect with a first one of the plurality of routing layers, and wherein others of the second plurality of conductive vias connect with a second one of the plurality of routing layers.

32. The interconnection component of claim 29, wherein the at least some of the contacts are exposed surfaces of the vias.

33. The interconnection component of claim 27, wherein the at least some of the contacts include electrically conductive pads.

34. The interconnection component of claim 33, further comprising traces extending along the first surface between the vias and the pads.

35. A microelectronic assembly including an interconnection component as claimed in claim 29, further comprising a microelectronic element having contacts on a contact-bearing face thereof facing the first surface of the low-CTE element, the contacts of the microelectronic element being joined to corresponding contacts on the low-CTE element through masses of bond material.

36. A method of making an interconnection component, comprising:
assembling a low-coefficient of thermal expansion (“CTE”) element with a sheet-like dielectric element and with a dielectric bonding layer between major surfaces of the low-CTE element and the dielectric element, the low-CTE element consisting essentially of a material having a first CTE of less than 10 parts per million per degree Celsius (“ppm/° C.”), wherein a plurality of metalized vias extend through the dielectric bonding layer and at least partially through the low-CTE element, the dielectric element having a CTE at least 50% greater than the first CTE and being greater than 10 ppm/° C.;
forming conductive elements and terminals overlying the dielectric element; and
after the assembling step, forming contacts overlying the low-CTE element by depositing electrically conductive material to contact the metalized vias.

37. The method of claim 36, wherein the dielectric element includes a plurality of sheet-like dielectric elements layered along the thickness thereof and including routing circuitry having a plurality of routing layers embedded among the plurality of sheet-like dielectric elements, the routing layers electrically connected with each other through the sheet-like elements.

38. The method of claim 36, wherein the step of forming conductive elements and terminals includes laminating a second sheet-like dielectric element to an exposed surface of the first dielectric element, and forming the conductive elements extending through the first and second dielectric elements.

39. The method of claim 36, wherein the step of forming the contacts includes forming electrically conductive traces and electrically conductive pads connected with the traces.

40. The method of claim 36, wherein the low-CTE element has a thickness, and wherein the metalized vias are formed partially through the low-CTE element at a distance less than the thickness thereof.

41. The method of claim 40, wherein the step of forming the contacts includes grinding the low-CTE element after the assembling step to expose the metalized vias.

42. The method of claim 41, wherein the low-CTE element has a thickness of at least 600 microns during the step of assembling, and wherein the step of grinding reduces the thickness of the low-CTE element to 200 microns or less.

43. The method of claim 36, wherein the step of assembling includes applying the dielectric bonding layer between the low-CTE element and the dielectric element and holding the low-CTE element and the dielectric element between first and second spaced-apart and parallel plates for a predetermined duration that includes curing of the bonding layer.

44. The method of claim 41, wherein the step of forming the contacts includes forming electrically conductive traces and electrically conductive pads connected with the traces.

45. The method of claim 36, wherein the step of assembling is carried out with the low-CTE element and the dielectric element in the form of one of a panel or a wafer, and wherein the method further includes the step of segmenting the resulting assembly into a plurality of in-process units, at least one of which is further acted upon according to the steps of forming metalized vias, conductive elements and terminal, and contacts.

46. The method of claim 36, further including a step of embedding a glass fiber sheet in the dielectric layer to form a stiffener therein, wherein the stiffener has major surface having an area not greater than an area of a contact-bearing surface of a microelectronic element to be mounted overlying the major surface of the stiffener, the area of the stiffener being greater than 50% of the area of the microelectronic element.

47. The method of claim 36, wherein the step of assembling includes spinning a dielectric bonding material onto the low-CTE layer to form the dielectric bonding layer.

48. A method of making an interconnection component, comprising:
assembling a low-coefficient of thermal expansion (“CTE”) element with a dielectric element and with a dielectric bonding layer between major surfaces of the low-CTE element and the dielectric element, the low-CTE element consisting essentially of a material having a first CTE of less than 10 parts per million per degree Celsius (“ppm/° C.”);
forming a plurality of metalized vias extending through the dielectric bonding layer and at least partially through the low-CTE element, the dielectric element having a CTE at least 50% greater than the first CTE and being greater than 10 ppm/° C.;
forming conductive elements and terminals overlying the dielectric element; and
after the forming step, forming contacts overlying the low-CTE element by depositing electrically conductive material to contact the metalized vias.

49. The method of claim 48, wherein the step of forming the plurality of metalized vias is carried out after the assembling step.

50. The method of claim 48, wherein the dielectric element includes routing circuitry having pads exposed at the second surface thereof, and wherein the step of forming the plurality of metalized vias includes forming a plurality of openings in the low-CTE element and through the bonding layer to expose the pads.

51. The method of claim 50, wherein the step of forming the plurality of metalized vias includes depositing metal into the openings to contact the pads and to fill the openings.

52. A method of making an interconnection component, comprising:
assembling a low-coefficient of thermal expansion (“CTE”) element with a sheet-like dielectric element and with a dielectric bonding layer between major surfaces of the low-CTE element and the dielectric element, the low-CTE element consisting essentially of a material having a first CTE of less than 10 parts per million per degree Celsius (“ppm/° C.”), wherein a plurality of first metalized vias extend through the low-CTE element, the dielectric element having a CTE at least 50% greater than the first CTE and being greater than 10 ppm/° C.;
forming conductive elements and terminals overlying the dielectric element; and
after the assembling step, forming second metalized vias through the bonding layer and the dielectric element, the second metalized vias electrically connected between the first metalized vias and the conductive elements.

53. The method of claim 52, further including forming contacts overlying the low-CTE element by depositing electrically conductive material to contact the metalized vias.

54. The method of claim 52, wherein the step of forming conductive elements and terminals includes laminating a second sheet-like dielectric element to an exposed surface of the first dielectric element, and forming the conductive elements extending through the first and second dielectric elements and further overlying the second dielectric element.

55. The method of claim 54, wherein the at least some of the second metalized vias are directly electrically connected with the conductive elements overlying the first dielectric element, and wherein others of the second metalized vias are directly electrically connected with the conductive elements overlying the second dielectric element.

56. The method of claim 52, wherein the step of forming the contacts includes grinding the low-CTE element after the assembling step to expose the metalized vias.
